(19) United States
(12) Patent Application Publication
(10) Pub. No.: US 2004/0109338 A1
(43) Pub. Date: Jun. 10, 2004

(54) Ternary content addressable memory cell

(75) Inventor: Seong-Ho Jeung, Suwon-shi (KR)

Correspondence Address: Frank Chau, F. CHAU & ASSOCIATES, LLP, Suite 501, 1900 Hempstead Turnpike, East Meadow, NY, 11554, US

(73) Assignee: Samsung Electronics Co., Ltd.

(21) Appl. No.: 10/721,012

(22) Filed: Nov. 24, 2003

(30) Foreign Application Priority Data
Dec. 4, 2002 (KR) 2002-76578

(51) Int. Cl. G11C 17/00

(52) U.S. Cl. 365/95

(57) ABSTRACT

A ternary CAM cell includes a main memory cell, a mask memory cell, a match line, a mask circuit, and a comparison circuit, where the main memory cell is enabled to a wordline to store data, and the mask memory cell enabled to a wordline to store mask data, data transferred to/from the main memory cell is loaded on a bitline pair, and mask data transferred to a mask memory cell is loaded on a mask bitline pair, comparison data is loaded on a comparison signal line pair, while the mask circuit is coupled between the match line and the mask memory cell to receive the comparison data, and the comparison circuit is coupled between the mask circuit and a ground voltage and includes a pair of transistors coupled to a comparison signal line pair and a pair of match transistors coupled to the data of the main memory cell such that, although the voltage level of the comparison data is lowered, a low voltage operation characteristic is excellent, the capacitive loadings of comparison signal lines are constantly maintained, and operation cycles decrease in number.

### FIELD OF THE INVENTION

The present invention relates to a content addressable memory and, more particularly, a ternary content addressable memory cell.

### BACKGROUND OF THE INVENTION

Unlike the address-based random access memory for searching data in a specific address, a content addressable memory (hereinafter referred to as “CAM”) can be instructed to compare a specific pattern of comparand data with data stored in its associative CAM array. The entire CAM array is searched in parallel for a match with the comparand data. If there is a match, the CAM device indicates the match by asserting a match flag. Multiple matches may also be indicated by asserting a multiple match flag. The CAM device typically includes a priority encoder to translate the highest priority matching location into a match address or CAM index.

Binary CAM cells are able to store two states of information: a logic high state and a logic low state. Binary CAM cells typically include a RAM cell and a comparison circuit. The comparison circuit compares the comparand data with data stored in the RAM cell and drives a match line to a predetermined state when there is a match. Ternary CAM cells store three states of information: a logic high state, a logic low state, and a don't care state. The local mask data masks the comparison result of the comparand data with the data stored in the first RAM cell such that the comparison result does not affect the match line. Accordingly, the ternary CAM cell offers more flexibility to the user which seeks the compare data.

FIG. 1 shows a conventional ternary CAM cell as disclosed in U.S. Pat. No. 6,514,384. Referring to FIG. 1, a ternary CAM cell 200 includes a main memory cell 202, a mask circuit 206, a mask memory cell 208, a comparison circuit 104, and a precharge circuit 216. The main memory cell 202 is a bi-stable memory circuit having two inverters 222 and 224, in which one output is cross-coupled to another output between nodes 219 and 221. The node 219 stores data D, and the node 221 stores complementary data DB. The main memory cell 202 further includes pass transistors 218 and 220 which connect the nodes 219 and 221 with a bitline BL and a complementary bitline BLB in response to the logic state of a main wordline WL, respectively.

The mask memory cell 208 is a bi-stable memory circuit having two inverters 226 and 228 that are cross-coupled to each other, which is similar to the main memory cell 202. A node 229 stores mask data MD, and a node 231 stores complementary mask data MDB that is logically complementary with the mask data MD. The nodes 229 and 231 are connected with the bitline BL and the complementary bitline BLB through pass transistors 230 and 232 in response to the logic state of a mask wordline MWL, respectively. The node 231 is coupled to the gate of a mask transistor 206.

The comparison circuit 104 compares data stored in the main memory cell 202 with comparison data provided on the comparison signal lines CMP and CMPB. The comparison circuit 104 has transistors 110, 112, and 114 for performing a comparing operation. The transistor 110 has a source coupled to the complementary CMPB, a drain coupled to a node 111, and a gate coupled to a node 219 storing the data D of the main memory cell 202. The transistor 112 has a source coupled to the comparison signal line CMP, a drain coupled to the node 111, and a gate coupled to a node 221 storing the complementary data DB of the main memory cell 202. The transistor 114 is a match transistor. In the case that the comparison data is identical with the data stored in the main memory cell, the transistor 114 lays down to a low level unless the mask transistor 206 masks the comparison result.

Nonetheless, the CAM device 200 of FIG. 1 suffers from problems as follows.

First, a low voltage characteristic is degraded. Since the transistors 110 and 112 of the comparison circuit 104 are typically NMOS transistors, a threshold voltage of the NMOS transistor drops to prevent the VDD voltage level on the comparison signal lines CMP and CMPB from fully transmitting to the node 111.

Second, the capacitive loading of the respective comparison signal lines CMP and CMPB may become different according to the state of data stored in the main memory cell 202. That is, when “1” is stored in D of the main memory cell 202, the transistor 110 is turned on. The transistor 110 is associated with the capacitive loading of the comparison signal line CMP, and the transistor 112 is associated with the capacitive loading of the complementary comparison signal line CMPB. When the same data are stored in the main memory cells 202, there is a large difference between the capacitive loadings of the comparison signal lines CMP and CMPB.

Third, a main wordline WL and a mask wordline MWL are separated from each other. Data of the main memory cell 202 and data of the mask memory cell 208 are transmitted to the bitline BL and the complementary bitline BLB. In this case, the main wordline and the mask wordline must be separated from each other, and their enable times must be separated from each other so as to transfer data to the main memory cell 202 and the mask memory cell 208. Accordingly, two data write operations are used: one is for writing data to the main memory cell 202, and the other is for writing data to the mask memory cells 208. The two data write operations make an operation cycle time longer.

On the other hand, a ternary CAM cell 106 of FIG. 2 includes a main memory cell 102 and a mask memory cell 108 which have the same construction as shown in FIG. 1. Further, the ternary CAM cell 106 includes a match detector 120 for comparing data stored in the main memory cell 102 with search data. The match detector 120 has transistors 116, 50a, 52a, 50b, and 52b between a match line ML and a ground voltage. The transistors 116, 50a, 52a, 50b, and 52b gate to lines /M, D, BL, /D, and /BL, respectively. Similar to the ternary CAM cell of FIG. 1, the main memory cell 102 is driven by a main wordline DWL and the mask memory cell 108 is driven by a mask wordline MWL. Since the main wordline DWL and the mask wordline MWL are separated from each other, an operation cycle time becomes longer.

### SUMMARY OF THE INVENTION

A feature of the invention is to provide a ternary CAM device which has a stable low voltage operation characteristic and constant capacitive loading of comparison signal lines to shorten an operation cycle time.

According to the present invention, a ternary CAM cell includes a main memory cell, a mask memory cell, a match line, a mask circuit, and a comparison circuit. The main memory cell is enabled to a wordline to store data, and the mask memory cell is enabled to a wordline to store mask data. Data transferred to and/or from the main memory cell is loaded on a bitline pair, and mask data transferred to a mask memory cell is loaded on a mask bitline pair. Further, comparison data is loaded on a comparison signal line pair. The mask circuit is coupled between the match line and the mask memory cell to receive the comparison data. The comparison circuit is coupled between the mask circuit and a ground voltage and includes a pair of transistors coupled to a comparison signal line pair and a pair of match transistors coupled to the data of the main memory cell.

### BRIEF DESCRIPTION OF THE DRAWINGS

The present disclosure provides a ternary content addressable memory cell in accordance with the following exemplary figures, in which:

FIG. 1 shows an example of a conventional ternary CAM cell;

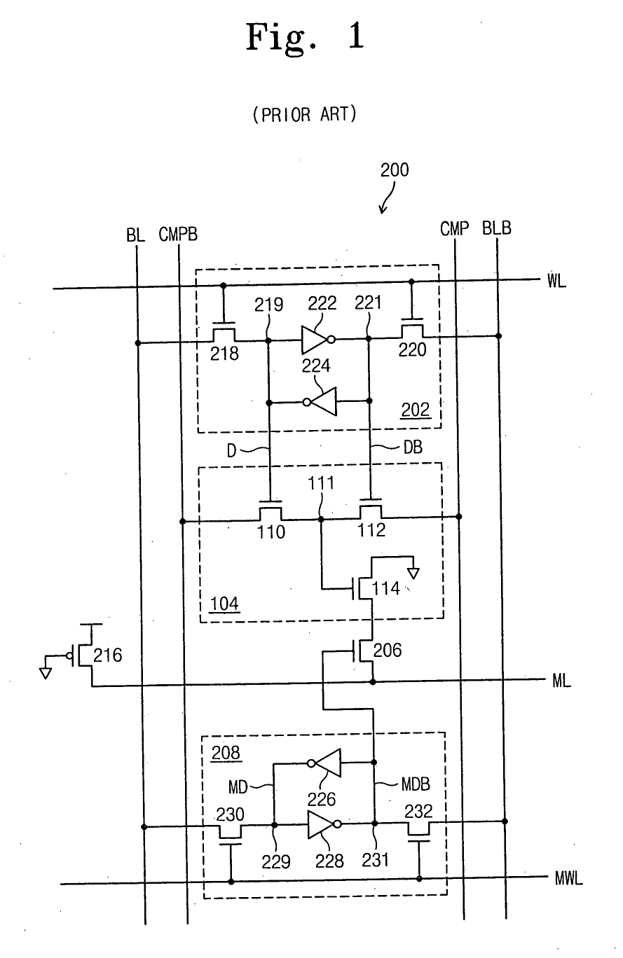

FIG. 2 shows another example of a conventional ternary CAM cell;

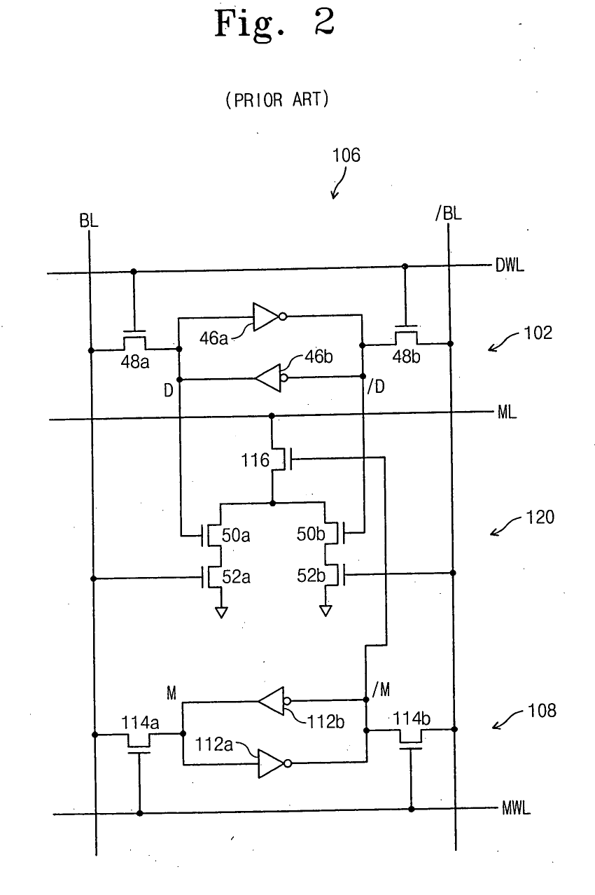

FIG. 3 shows a ternary CAM cell according to a first embodiment of the present invention;

FIG. 4 shows a ternary CAM cell according to a second embodiment of the present invention;

FIG. 5 shows a ternary CAM cell according to a third embodiment of the present invention; and

FIG. 6 shows a ternary CAM cell according to a fourth embodiment of the present invention.

### DESCRIPTION OF THE PREFERRED EMBODIMENT

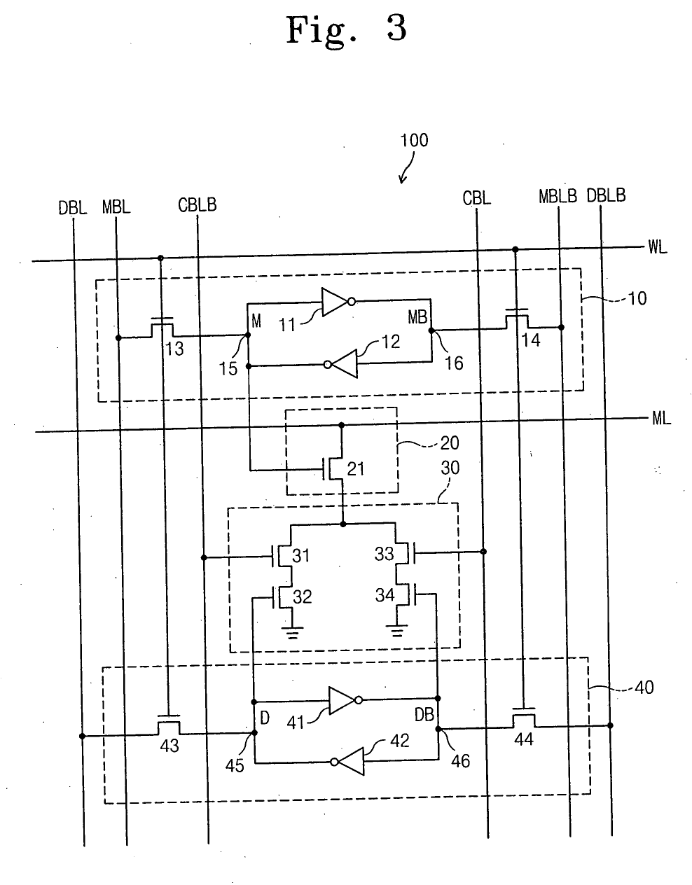

A ternary CAM cell according to an embodiment of the present invention is now described below with reference to FIG. 3.

Referring to FIG. 3, a ternary CAM cell 100 includes a mask memory cell 10, a mask circuit 20, a comparison circuit 30, and a main memory cell 40. The mask memory cell 10 is a bi-stable memory circuit having two inverters 11 and 12 between nodes 15 and 16, in which one output and one input are cross-coupled to each other. The node 15 stores mask data M, and the node 16 stores complementary mask data MB. The mask memory cell 10 further includes pass transistors 13 and 14 which connect the nodes 15 and 16 with a mask bitline MBL and a complementary mask bitline MBLB in response to the logic state of a wordline WL, respectively.

The mask circuit 20 is composed of an NMOS transistor 21 which is coupled between the match line ML and the comparison circuit 30 and responds to the mask data M of the mask memory cell 10.

The comparison circuit 30 includes first to fourth NMOS transistors 31, 32, 33, and 34 which are coupled between the mask circuit 20 and the main memory cell 40. The first and second NMOS transistors 31 and 32 are serially coupled between the NMOS transistor 21 of the mask circuit 20 and a ground voltage. The first NMOS transistor 31 gates to the complementary comparison signal line CBLB, and the second NMOS transistor 32 gates to the data D of the main memory cell 40. The third and fourth NMOS transistors 33 and 34 are serially coupled between the NMOS transistor 21 of the mask circuit 20 and a ground voltage. The third NMOS transistor 33 gates to a comparison signal line CBL, and the fourth NMOS transistor 34 gates to complementary data DB of the main memory cell 40. The first and third NMOS transistors 31 and 33 operate by means of comparison data of the comparison signal line pair CBLB and CBL. The second and fourth NMOS transistors 32 and 34 become match transistors which operate by means of the data and complementary data D and DB of the main memory cell 40.

The main memory cell 40 includes two inverters 41 and 42 which are cross-coupled between the nodes 45 and 46. The data D is stored on the node 15, and the complementary data DB is stored on the node 46. The main memory cell 40 further includes pass transistors 43 and 44 which connect the nodes 45 and 46 with a data bitline DBL and a complementary data bitline DBLB in response to the logic state of a wordline WL, respectively.

Now, the operation of the ternary CAM cell 100 is explained in detail. It is assumed that data D “0” and the complementary data DB “1” are stored by a write operation to the main memory cell 40. Further, it is assumed that the match line ML, the mask bitline MBL, and the complementary mask bitline MBLB are precharged to a power supply voltage level, and the comparison signal line CBL and the complementary comparison signal line CBLB is precharged to a ground voltage level.

When data “0” is inputted to the mask bitline MBL and the wordline WL is enabled, mask data M of the mask memory cell 10 is stored as “0” and complementary mask data MB thereof is stored as “1”. The NMOS transistor 21 of the match circuit 20 is turned off in response to the mask data M “0”. Therefore the match line ML is maintained at the level of the precharge power supply voltage VDD, which means that the data of the main memory cell 40 is regarded as “match” irrespective of the pattern of the mask data M. The foregoing data matching method is used in the case that a group of data (e.g., 0-15) is searched or a fingerprint sensor is regarded as a “match” with imprecise data such as fingerprint edge data or hand-around sector data in a pattern matching method such as fingerprint identification.

On the other hand, when the data “1” is inputted to the mask bitline MBL and the wordline WL is enabled, the mask data of the mask memory cell 10 is stored as “1” and the complementary mask data MB thereof is stored as “0”. The mask data M “1” means that the result of the comparison circuit 30 is not masked. The NMOS transistor 21 of the match circuit 20 is turned on in response to the mask data “1”. In order to detect whether the data D stored in the main memory cell 40 is “0”, the complementary comparison signal line CBLB transitions from a precharge ground voltage level to a power supply voltage level, and the comparison signal line CBL is maintained at the precharge ground voltage level. The first NMOS transistor 31 of the comparison circuit 30 is turned on in response to the complementary signal line CBLB of the power supply voltage (“VDD”) level, while the second NMOS transistor 32 thereof is turned off in response to the data D “0” of the main memory cell 40. Further, the third NMOS transistor 33 thereof is turned off in response to the precharge ground voltage (“GND”) level. Therefore, since the second and third NMOS transistors 32 and 33 of the match circuit 20 are turned off although the NMOS transistor 21 thereof is turned on, the match line ML is maintained at the power supply voltage level. This means that the data D stored in the main memory cell 40 matches with “0”.

In order to detect whether the data D stored in the main memory cell 40 is “1”, the comparison signal line CBL transitions from the precharge ground voltage level to the power supply voltage level, and the complementary comparison signal line CBLB is maintained at the precharge ground voltage level. The first NMOS transistor 31 is turned off in response to the precharge ground voltage (GND) level of the complementary comparison signal line CBLB. Further, the third NMOS transistor 33 of the comparison circuit 30 is turned on in response to the comparison signal line CBL of the power supply voltage (VDD) level, and the fourth NMOS transistor 34 thereof is turned on in response to the complementary data “1” of the main memory cell 40. Accordingly, in response to the mask data M “1”, the NMOS transistor 21 of the match circuit 20 is turned on and the third and fourth NMOS transistors 33 and 34 of the comparison circuit 30 are turned on. This means that the data D of the main memory cell 40 does not match with “1”.

According to the invention, the ternary CAM cell 100 includes the comparison circuit 30 having the first to fourth transistors 31, 32, 33, and 34 of an excellent low voltage operation characteristic. Therefore, the ternary CAM cell 100 stably operates even if the voltage level of the comparison data on the comparison signal lines CBLB and CBL is lowered. Since a direct path is not formed between the comparison signal lines CBLB and CBL and the main memory cell data D and DB, the capacitive loadings of the comparison signal lines CBLB and CBL are constantly maintained. Further, since the bitlines BL and BLB coupled to the main memory cell 40 and the mask bitlines MBL and MBLB coupled to the mask memory cell 10 are separated from each other and the main memory cell 40 and the mask memory cell 10 are coupled to one wordline WL, the write and read operations to/from the main memory cell 40 and the mask memory cell 10 are conducted at the same time. Thus, the operation cycles of the ternary CAM cell 100 can decrease in number.

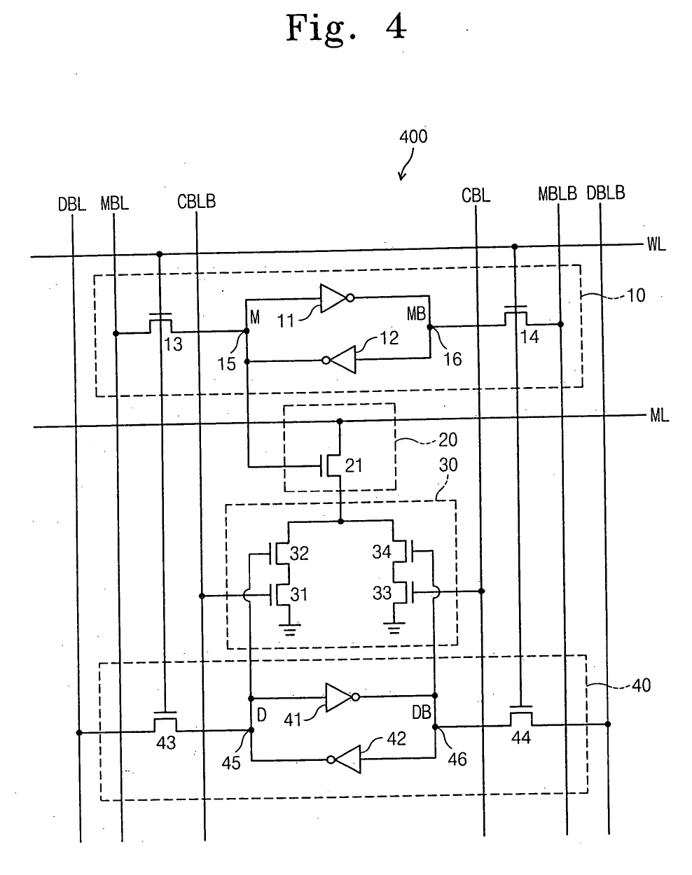

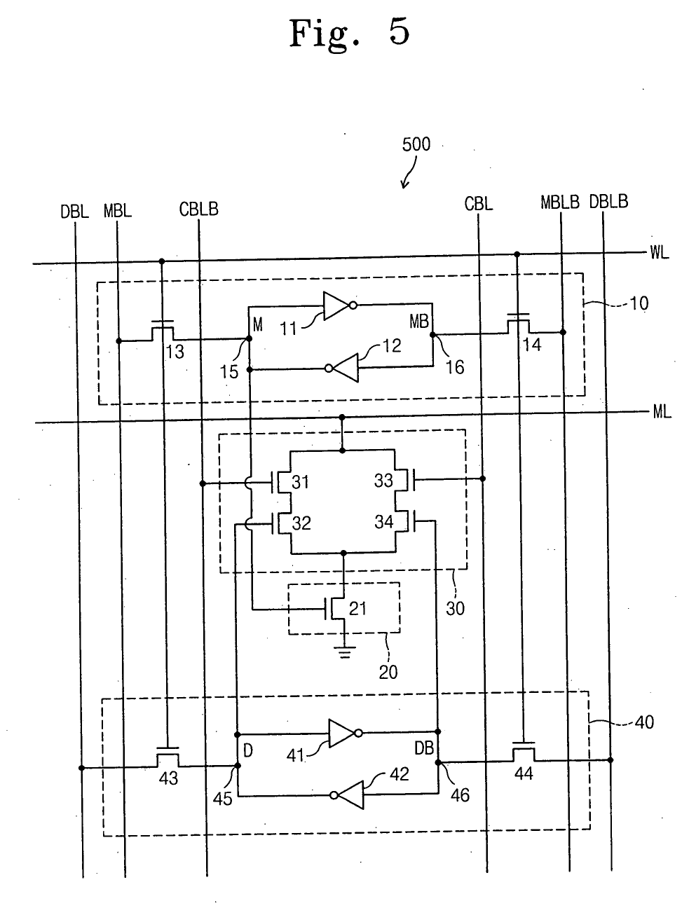

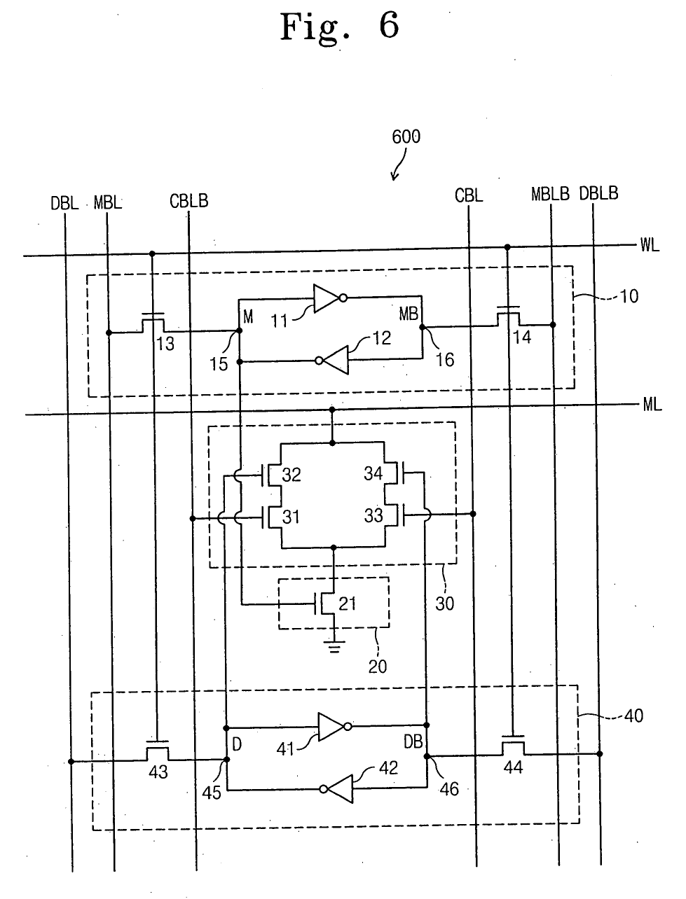

It will be understood that by combining the connection relationships between the match circuit 20 and the comparison circuit 30 shown in FIG. 3, the present invention is applicable to modified connections shown in FIGS. 4, 5, and 6. The operations of the circuits of FIGS. 4, 5, and 6 are identical with the operation of the circuits of FIG. 3, and will not be explained in further detail.

According to the above-described ternary CAM cell, although the voltage level of the comparison data is lowered, a low voltage operation characteristic is excellent, the capacitive loadings of comparison signal lines are constantly maintained, and operation cycles decrease in number.

While the above exemplary embodiments have been described in considerable detail, numerous variations and modifications will become apparent to those skilled in the art once the above disclosure is fully appreciated. It is intended that the following claims be interpreted to embrace all such variations and modifications.

What is claimed is:

1. A ternary content addressable memory (“CAM”) cell comprising:
a main memory cell enabled to a wordline to store data;
a mask memory cell enabled to the wordline to store mask data;
a bitline pair for transmitting the data to or from the main memory cell;
a mask bitline pair for transmitting the mask data to the mask memory cell;
a comparison signal line pair for transmitting comparison data;
a match line;
a mask circuit for receiving the mask data, the mask circuit being coupled to the match line and the mask memory cell; and
a comparison circuit including a pair of transistors coupled to the comparison signal line pair and a pair of match transistors coupled to data of the main memory cell, the comparison circuit being coupled to a ground line of the mask circuit.

2. The ternary CAM cell of claim 1, characterized in that the comparison circuit includes:
a first NMOS transistor having a drain coupled to the mask circuit and a gate coupled to the comparison data;
a second NMOS transistor having a drain coupled to the mask circuit and a gate coupled to a comparison data line;
a first match NMOS transistor having a drain coupled to the first NMOS transistor, a gate coupled to the data of the main memory cell, and a source coupled to a ground voltage; and
a second match NMOS transistor having a drain coupled to the second NMOS transistor, a gate coupled to complementary data of the main memory cell, and a source coupled to a ground voltage.

3. The ternary CAM cell of claim 1, characterized in that the comparison circuit includes:
a first match NMOS transistor having a drain coupled to the mask circuit and a gate coupled to the data of the main memory cell;
a second match NMOS transistor having a drain coupled to the mask circuit and a gate coupled to the complementary data of the main memory cell;
a first NMOS transistor having a drain coupled to a source of the first NMOS transistor, a gate coupled to the comparison signal line, and a source coupled to a ground voltage; and
a second NMOS transistor having a drain coupled to a source of the second NMOS transistor, a gate coupled to the comparison signal line, and a source coupled to a ground voltage.

4. The ternary CAM cell of claim 1, characterized in that the mask circuit is an NMOS transistor which is coupled between the match line and the comparison circuit and is gated by the mask data.

5. A ternary content addressable memory (“CAM”) cell comprising:
a main memory cell enabled to a wordline to store data;
a mask memory cell enabled to the wordline to store mask data;
a bitline pair for transmitting the data to or from the main memory cell;
a mask bitline pair for transmitting the mask data to the mask memory cell;
a comparison signal line pair for transmitting comparison data;
a match line;
a mask circuit for receiving the mask data, the mask circuit being coupled to the mask memory cell; and
a comparison circuit including a pair of transistors coupled to the comparison signal line pair and a pair of match transistors coupled to data of the main memory cell, the comparison circuit being coupled between the match line and the mask circuit

6. The ternary CAM cell of claim 5, characterized in that the comparison circuit includes:
a first NMOS transistor having a drain coupled to the match line and a gate coupled to the comparison data line;
a second NMOS transistor having a drain coupled to the match line and a gate coupled to a complementary comparison data line;
a first match NMOS transistor having a drain coupled to a source of the first NMOS transistor and a gate coupled to the data of the main memory cell; and
a second match NMOS transistor having a drain coupled to a source of the second NMOS transistor, a gate coupled to complementary data of the main memory cell, and a source coupled to a source of the main memory cell.

7. The ternary CAM cell of claim 5, characterized in that the comparison circuit includes:
a first match NMOS transistor having a drain coupled to the match line and a gate coupled to the data of the main memory cell;
a second match NMOS transistor having a drain coupled to the match line and a gate coupled to the complementary data of the main memory cell;
a first NMOS transistor having a drain coupled to a source of the first match NMOS transistor and a gate coupled to the comparison signal line; and
a second NMOS transistor having a drain coupled to a source of the second match NMOS transistor, a gate coupled to a complementary comparison signal line, and a source coupled to a source of the first NMOS transistor.

8. The ternary CAM cell of claim 5, characterized in that the mask circuit is an NMOS transistor which is coupled between the match line and the comparison circuit and is gated by the mask data.

9. A ternary content addressable memory (“CAM”) cell comprising:
a wordline;
a main memory cell in signal communication with the wordline for storing data;
a bitline pair in signal communication with the main memory cell for transmitting data to or from the main memory cell;
a mask memory cell in signal communication with the wordline for storing mask data;
a mask bitline pair in signal communication with the mask memory cell for transmitting mask data to the mask memory cell;
a comparison circuit in signal communication with the main memory cell and the mask circuit;
a comparison signal line pair in signal communication with the comparison circuit for transmitting comparison data;
a mask circuit in signal communication with the mask memory cell and the comparison circuit for receiving the mask data; and
a match line in signal communication with at least one of the mask circuit and the comparison circuit.

10. The ternary CAM cell of claim 9, the comparison circuit comprising a pair of transistors coupled to the comparison signal line pair and a pair of match transistors coupled to data of the main memory cell.

11. The ternary CAM cell of claim 9 wherein the comparison circuit is in signal communication with a ground line of the mask circuit.

12. The ternary CAM cell of claim 9 wherein the comparison circuit is in signal communication between the match line and the mask circuit.

13. The ternary CAM cell of claim 9, the comparison circuit comprising:
a first NMOS transistor having a drain coupled to the mask circuit and a gate coupled to a complimentary comparison data line of the comparison signal line pair;
a second NMOS transistor having a drain coupled to the mask circuit and a gate coupled to a comparison data line of the comparison signal line pair;
a first match NMOS transistor having a drain coupled to the first NMOS transistor, a gate coupled to the data of the main memory cell, and a source coupled to a ground voltage; and
a second match NMOS transistor having a drain coupled to the second NMOS transistor, a gate coupled to complementary data of the main memory cell, and a source coupled to a ground voltage.

14. The ternary CAM cell of claim 9, the comparison circuit comprising:
a first match NMOS transistor having a drain coupled to the mask circuit and a gate coupled to the data of the main memory cell;
a second match NMOS transistor having a drain coupled to the mask circuit and a gate coupled to the complementary data of the main memory cell;
a first NMOS transistor having a drain coupled to a source of the first match NMOS transistor, a gate coupled to a complementary comparison signal line of the comparison signal line pair, and a source coupled to a ground voltage; and
a second NMOS transistor having a drain coupled to a source of the second match NMOS transistor, a gate coupled to the comparison signal line of the comparison signal line pair, and a source coupled to a ground voltage.

15. A ternary content addressable memory (“CAM”) cell comprising:
wordline means for transmitting a word signal;
main memory cell means in signal communication with the wordline means for storing data;
bitline pair means in signal communication with the main memory cell means for transmitting data to or from the main memory cell means;
mask memory cell means in signal communication with the wordline means for storing mask data;
mask bitline pair means in signal communication with the mask memory cell means for transmitting mask data to the mask memory cell means;
comparison circuit means in signal communication with the main memory cell means and the mask circuit means;
comparison signal line pair means in signal communication with the comparison circuit means for transmitting comparison data;
mask circuit means in signal communication with the mask memory cell means and the comparison circuit means for receiving the mask data; and
match line means in signal communication with at least one of the mask circuit means and the comparison circuit means.

16. The ternary CAM cell of claim 15, the comparison circuit means comprising a pair of switching means coupled to the comparison signal line pair means and a pair of match switching means coupled to data of the main memory cell means.

17. The ternary CAM cell of claim 15 wherein the comparison circuit means is in signal communication with a grounding means of the mask circuit means.

18. The ternary CAM cell of claim 15 wherein the comparison circuit means is in signal communication between the match line means and the mask circuit means.

19. The ternary CAM cell of claim 15, the comparison circuit means comprising:
a first switching means having a drain coupled to the mask circuit means and a gate coupled to a complimentary comparison data line of the comparison signal line pair means;
a second switching means having a drain coupled to the mask circuit means and a gate coupled to a comparison data line of the comparison signal line pair means;
a first match switching means having a drain coupled to the first switching means, a gate coupled to the data of the main memory cell means, and a source coupled to a grounding means; and
a second match switching means having a drain coupled to the second switching means, a gate coupled to complementary data of the main memory cell means, and a source coupled to a grounding means.

20. The ternary CAM cell of claim 15, the comparison circuit means comprising:
a first match switching means having a drain coupled to the mask circuit means and a gate coupled to the data of the main memory cell means;
a second match switching means having a drain coupled to the mask circuit means and a gate coupled to the complementary data of the main memory cell means;
a first switching means having a drain coupled to a source of the first match switching means, a gate coupled to a complementary comparison signal line of the comparison signal line pair means, and a source coupled to a grounding means; and
a second switching means having a drain coupled to a source of the second match switching means, a gate coupled to the comparison signal line of the comparison signal line pair means, and a source coupled to a grounding means.
